(19) United States
(12) Patent Application Publication
(10) Pub. No.: US 2026/0334088 A1
(43) Pub. Date: Oct. 22, 2026

(54) NEUROMORPHIC DEVICE

(71) Applicant: Samsung Electronics Co., Ltd., Gyeonggi-do (KR)

(72) Inventors: Dmytro APALKOV, San Jose, CA (US); Roman CHEPULSKYY, Milpitas, CA (US); Jaewoo JEONG, Los Altos, CA (US); FNU IKHTIAR, San Jose, CA (US)

(21) Appl. No.: 19/368,418

(22) Filed: Oct. 24, 2025

Related U.S. Application Data
(60) Provisional application No. 63/790,299, filed on Apr. 17, 2025.

(51) Int. Cl. H10N 50/10; G06N 3/063; H10B 61/00; H10N 50/01; H10N 50/85

(52) U.S. Cl. CPC H10N 50/10; G06N 3/063; H10B 61/20; H10N 50/01; H10N 50/85

(57) ABSTRACT

A magnetic device is provided. The magnetic device includes: a first free layer, wherein the first free layer includes a ferromagnetic material; and a first capping layer disposed on the first free layer, wherein the first capping layer includes an in-plane anisotropy inducing material.

### CROSS-REFERENCE TO RELATED APPLICATION

This application claims the priority benefit under 35 U.S.C. § 119(e) of U.S. Provisional Application No. 63/790,299, filed on Apr. 17, 2025, the disclosure of which is incorporated by reference in its entirety as if fully set forth herein.

### TECHNICAL FIELD

The disclosure generally relates to magnetic devices for computing applications. More particularly, the subject matter disclosed herein relates to neuromorphic devices employing magnetic tunnel junctions (MTJs) having improved high-frequency operation.

### BACKGROUND

Neuromorphic computing aims to emulate brain-like processing using hardware devices that exhibit stochastic switching behavior. Unlike deterministic computing, neuromorphic systems rely on probabilistic elements that capture randomness and variability. Such hardware supports energy-efficient operations for tasks such as pattern recognition and decision making.

### SUMMARY

Accordingly, an aspect of the disclosure provides a magnetic device including a probabilistic free layer and a capping layer formed from a material such as Ir, Os, Te, or Tl, which induces in-plane magnetic anisotropy in the free layer. This anisotropy increases demag energy when the magnetization precesses out of the plane of the layer and enables high-frequency stochastic switching behavior, making the device well suited for probabilistic logic and neuromorphic computing applications.

In an embodiment, a magnetic device comprises a first free layer, wherein the first free layer includes a ferromagnetic material; and a first capping layer disposed on the first free layer, wherein the first capping layer includes an in-plane anisotropy inducing material.

In an embodiment, a system comprises: a circuit; and a magnetic tunnel junction (MTJ) device within the circuit, the MTJ device including: a reference layer having a fixed magnetization direction; a tunnel barrier disposed on the reference layer; a free layer disposed on the tunnel barrier, the free layer including a ferromagnetic material; and a capping layer disposed on the free layer, wherein the capping layer includes an in-plane anisotropy inducing material.

In an embodiment, a method of forming a magnetic device comprises: forming a first free layer including a ferromagnetic material; forming a second free layer including a ferromagnetic material; and disposing an insertion layer between the first free layer and the second free layer, wherein the insertion layer includes an in-plane anisotropy inducing material.

### BRIEF DESCRIPTION OF THE DRAWINGS

In the following section, the aspects of the subject matter disclosed herein will be described with reference to exemplary embodiments illustrated in the figures, in which:

FIG. 1 is a diagram illustrating simulated stochastic switching behavior of a probabilistic free layer with and without an in-plane anisotropy (IMA) capping layer, according to an embodiment;

FIG. 2 is a cross-sectional diagram of a magnetic tunnel junction (MTJ) device including a probabilistic free layer and an IMA capping layer, according to an embodiment;

FIG. 3 is a cross-sectional diagram of an MTJ device including multiple free layers separated by IMA-inducing insertion layers, according to an embodiment;

FIG. 4 is a cross-sectional diagram of an MTJ device including a dual capping structure over the free layer, according to an embodiment;

FIG. 5 is a cross-sectional diagram of a magnetic device including a synthetic antiferromagnet (SAF) free layer structure coupled through an RKKY spacer, according to an embodiment;

FIG. 6 is a cross-sectional diagram of a magnetic device including an SAF free layer structure with embedded magnetic insertion layers, according to an embodiment;

FIG. 7 includes flowcharts illustrating methods of forming a magnetic device, according to an embodiment; and

FIG. 8 is a block diagram of an electronic device having a memory that incorporates MTJ structures and methods described in FIGS. 1-7, according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments.

Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “predetermined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. The dimensions of some of the elements may be exaggerated relative to other elements for clarity. For example, the dimensions of layers and regions may be exaggerated for clarity of illustration.

Further, if considered appropriate, reference numerals may be repeated among the figures to indicate corresponding and/or analogous elements. That is, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

“Free layer” as used herein refers to a ferromagnetic layer whose magnetization direction is changeable in response to thermal fluctuations or spin-torque effects. Some examples of “free layer” are CoFeB, CoFe, and other ferromagnetic materials suitable for stochastic switching. “Capping layer” as used herein refers to a layer disposed on a free layer to influence its magnetic properties, such as inducing in-plane magnetic anisotropy. Some examples of “capping layer” are layers including Ir, Os, Te, or Tl. “In-plane magnetic anisotropy” as used herein refers to a magnetic property where the easy axis of magnetization lies within the plane of the magnetic layer, favoring alignment parallel to the film surface. Some examples of “in-plane magnetic anisotropy” are anisotropy induced by interface effects between a ferromagnetic free layer and a capping layer composed of Ir, Os, Te, or Tl. “High saturation magnetization” as used herein refers to the maximum magnetization a ferromagnetic material can attain under an external magnetic field, indicating a strong magnetic response. Some examples of “high saturation magnetization” are found in materials such as CoFeB and CoFe, which exhibit saturation magnetization values above 1 Tesla.

“Reference layer” as used herein refers to a ferromagnetic layer with a fixed magnetization direction, serving as a reference for the free layer. Some examples of “reference layer” are CoFeB and CoFe layers pinned by antiferromagnetic materials like PtMn or IrMn. “Coupling layer” as used herein refers to a layer that mediates magnetic interaction between adjacent magnetic layers, such as promoting ferromagnetic or antiferromagnetic coupling. Some examples of “coupling layer” are Ru, Ir, Rh, and Os. “Intermediate magnetic layer” as used herein refers to a magnetic layer positioned between a reference layer and a tunnel barrier to assist in stabilizing or enhancing magnetic coupling. Some examples of “intermediate magnetic layer” are CoFeB and CoFe. “Tunneling barrier” as used herein refers to a thin insulating layer that allows quantum tunneling of electrons between adjacent magnetic layers in a magnetic tunnel junction. Some examples of “tunneling barrier” are MgO and Al₂O₃. “Antiferromagnetic material layer” as used herein refers to a layer in which adjacent atomic magnetic moments align in opposite directions, resulting in no net macroscopic magnetization, and which is used to pin the magnetization of an adjacent ferromagnetic layer. Some examples of “antiferromagnetic material layer” are PtMn and IrMn. “Magnetic insertion layer” as used herein refers to a magnetic layer inserted between free layers or adjacent to a free layer to modify coupling strength or magnetic behavior. Some examples of “magnetic insertion layer” are Fe, CoFe and CoFeB.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), etc. Semiconductor doping is the modification of electrical properties by doping, e.g., transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the structures that make up an IC device, lithography and etch pattern transfer steps are repeated multiple times. Each pattern being printed on the wafer is aligned to the previously formed patterns and slowly the conductors, insulators and selectively doped regions are built up to form the final device.

As noted above, neuromorphic computing aims to emulate brain-like processing using hardware devices that exhibit stochastic switching behavior. One approach involves MTJs, which can serve as probabilistic bits (p-bits) when designed to switch randomly between magnetic states. Achieving the high-frequency, thermally activated switching needed for such applications may involve engineering of the MTJ structure.

In some aspects, stochastic switching can be performed using free layers with in-plane magnetic anisotropy with reduced energy barriers. Such approaches may involve adjusting magnetic damping, modifying anisotropy or applying external fields in an effort to increase switching frequency.

However, these aspects may not consistently achieve high-frequency, uncorrelated switching without added complexity, instability or dependence on external fields. Additionally, they may not incorporate the material-level engineering sufficient to induce robust in-plane magnetic anisotropy for scalable, high-speed neuromorphic hardware.

Embodiments of the present disclosure provide a magnetic device that can be used for high-frequency, stochastic switching applications, such as probabilistic computing and random number generation. An aspect of the disclosure is an MTJ structure that includes a free layer composed of a ferromagnetic material and a capping layer disposed on the free layer. The capping layer includes one or more elements such as iridium (Ir), osmium (Os), tellurium (Te), or thallium (Tl), or alloys of these materials and is configured to induce in-plane magnetic anisotropy (IMA) in the free layer. These materials are chosen because their strong interfacial spin-orbit coupling, when in contact with ferromagnets such as CoFeB, alters the magnetic anisotropy at the interface and promotes an in-plane easy axis. This enhances the effective magnetic field when the magnetization goes out of the plane and enhances the precession frequency of such free layer. This interfacial engineering with Ir/Os/Te/Tl enables faster thermally driven magnetic switching behavior in the free layer, which aids in implementing stochastic bit (p-bit) behavior in hardware.

The present disclosure further extends to multiple embodiments that enhance the control and performance of the free layer's magnetic behavior. These include: (i) multilayer free layers with IMA-enhancing insertion layers disposed between them; (ii) stress-generating second capping layers (e.g., ScN, AlN) for added anisotropy tuning; (iii) synthetic antiferromagnetic (SAF) structures using two coupled free layers; and (iv) magnetic insertion layers (MILs), such as Fe, that boost IMA at key interfaces.

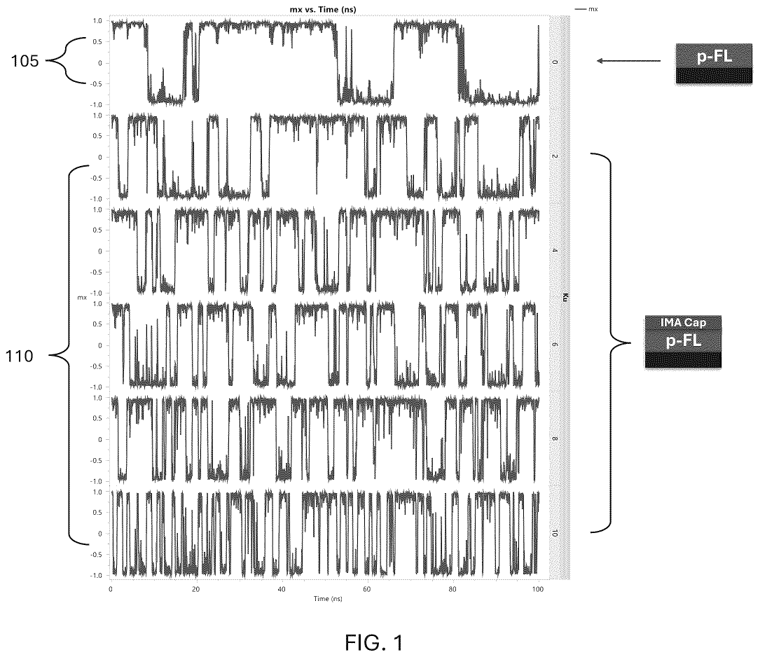

FIG. 1 illustrates simulated magnetization switching traces (mx vs. time (ns)) for MTJ devices operating in a stochastic regime. The upper trace 105 corresponds to an MTJ device that includes a probabilistic free layer (p-FL) without an IMA capping layer. In this configuration, the switching events occur less frequently, with extended dwell times in each magnetic state.

The lower set of traces 110 corresponds to MTJ devices in which the p-FL is combined with an IMA capping layer, according to an embodiment. Each trace represents stochastic magnetization behavior at different levels of IMA. Compared to the upper trace 105, the capped structures of the lower traces 110 exhibit higher-frequency thermally activated switching with reduced correlation between successive switching events. The frequency of the switching events increases with higher level of IMA (bottom of the plot). The IMA capping layer alters the interfacial anisotropy of the free layer, biasing its magnetization toward an in-plane orientation.

As illustrated, introducing the IMA capping layer enables more rapid and randomized p-bit behavior, which is advantageous for implementing probabilistic computing circuits and true random number generators. FIG. 1 demonstrates how material-level engineering of the free layer interface can improve stochastic performance without requiring external fields or added circuit complexity.

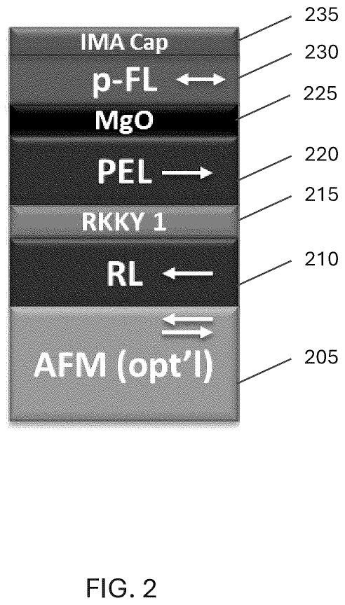

FIG. 2 is a cross-sectional diagram of an MTJ device including a probabilistic free layer and an IMA capping layer, according an embodiment.

In particular, FIG. 2 is a cross-sectional view of an MTJ device according to an embodiment of the present disclosure. The device includes a multilayer stack including, in order from bottom to top: an antiferromagnetic (AFM) layer 205, a reference layer (RL) 210, a coupling layer (RKKY1) 215, an intermediate magnetic layer or polarization enhancement layer (PEL) 220, a tunnel barrier layer (MgO) 225, a probabilistic free layer (p-FL) 230, and an IMA capping layer 235. The MTJ stack may be formed on a substrate with one or more underlayers (not shown) depending on fabrication requirements. In alternative embodiments, the AFM layer 205 can be omitted.

The AFM layer 205 may include one or more AFM materials such as platinum manganese (PtMn) or iridium manganese (IrMn), and is configured to pin the magnetization of the adjacent RL 210 via exchange bias. The RL 210 includes a ferromagnetic material, such as cobalt iron (CoFe) or cobalt iron boron (CoFeB), and typically maintains a fixed magnetization direction during device operation. The coupling layer 215 (denoted RKKY1) is a nonmagnetic spacer layer configured to induce antiferromagnetic coupling between the RL 210 and the intermediate magnetic layer 220 via the Ruderman-Kittel-Kasuya-Yosida (RKKY) interaction. Example materials for the coupling layer 215 include ruthenium (Ru), iridium (Ir), rhodium (Rh), or osmium (Os). An alloy or a multilayer of such materials can be used.

The intermediate magnetic layer 220 is a ferromagnetic layer, for example, composed of CoFeB, and forms part of a SAF reference stack in conjunction with the RL 210 and coupling layer 215. The tunnel barrier layer 225, disposed on the intermediate magnetic layer 220, is a thin insulating layer that permits spin-dependent quantum tunneling between the reference stack and the free layer 230. The tunnel barrier layer 225 may include magnesium oxide (MgO) or another oxide material that provides high tunneling magnetoresistance (TMR).

The probabilistic free layer 230 is disposed on the tunnel barrier layer 225 and is formed of a ferromagnetic material such as CoFeB, exhibiting high saturation magnetization (Ms) to support fast and thermally driven switching. The free layer 230 is designed to operate in a stochastic switching regime, making it well-suited for probabilistic computing hardware and true random number generators. Disposed on the free layer 230 is the IMA capping layer 235. The IMA capping layer 235 includes one or more heavy elements such as iridium (Ir), osmium (Os), tellurium (Te), or thallium (Tl), and is configured to induce IMA in the underlying free layer 230 through interfacial spin-orbit coupling. The enhanced IMA increases the frequency of thermally-activated precession between states by amplifying the out-of-plane magnetic field that arises whenever the thermally-driven magnetization precession results in an out-of-plane magnetization component. As a result, the IMA capping layer 235 effectuates higher-frequency stochastic switching (p-bit flipping), improving responsiveness in neuromorphic and probabilistic logic circuits. This anisotropy provides stable in-plane magnetization while preserving low energy barriers for stochastic magnetization switching, which is a key requirement for implementing p-bit (probabilistic bit) devices in neuromorphic and stochastic computing systems.

In another embodiment, the free layer 230 may be formed of different ferromagnetic alloys or composite ferromagnetic materials, such as NiFe, FeCo, or Heusler alloys, in place of CoFeB.

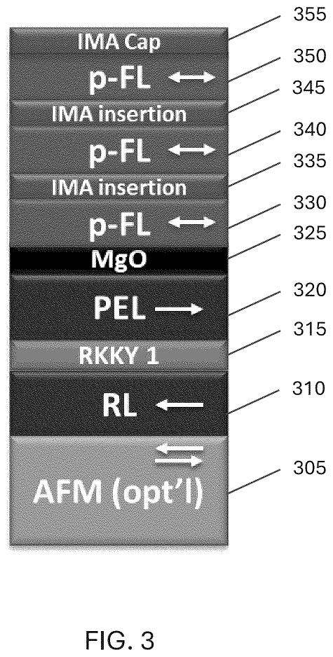

FIG. 3 is a cross-sectional diagram of an MTJ device including multiple free layers separated by IMA-inducing insertion layers, according an embodiment.

In particular, FIG. 3 is a cross-sectional view of an MTJ device according to another embodiment of the present disclosure. Similar to the device of FIG. 2, the device includes an AFM layer 305, a RL 310, a coupling layer (RKKY1) 315, a polarization enhancement layer (PEL) 320, a tunnel barrier layer 325, and a free layer structure disposed on the tunnel barrier layer 325. The AFM layer 305, RL 310, RKKY1 layer 315, and intermediate magnetic layer 320 may be formed of the same materials and function in the same manner as described with respect to FIG. 2, and thus are not repeated here in detail. In alternative embodiments, the AFM layer 305 can be omitted.

Unlike FIG. 2, the free layer structure of the device in FIG. 3 includes multiple ferromagnetic sub-layers separated by IMA-inducing insertion layers. In the illustrated embodiment, a first probabilistic free layer 330 is disposed on the tunnel barrier layer 325. The first free layer 330 includes a ferromagnetic material such as CoFeB, and is configured to operate in a stochastic switching regime, effectuating its use in probabilistic or neuromorphic computing circuits. Disposed on the first free layer 330 is a first insertion layer 335, which includes at least one of Ir, Os, Te, or Tl or alloys of such elements. This insertion layer is configured to induce IMA in the adjacent free layer, similar to the function of the capping layer 235 described in FIG. 2. The thickness of the first insertion layer 335 is selected to induce either ferromagnetic or antiferromagnetic coupling between the first and second free layers, depending on the desired overall magnetic behavior of the composite stack. The insertion layers of Ir, Os, Te, or Tl may have thicknesses that range from about 0.2 nm to 3.0 nm. In alternative embodiments, the thickness of the insertion layer can be different from the stated range.

A second free layer 340, formed of a ferromagnetic material such as CoFeB, is disposed on the first insertion layer 335. A second IMA-inducing insertion layer 345 is disposed on the second free layer 340, and may include the same IMA materials as the first insertion layer 335. The thickness of the second insertion layer 345 may also be varied like that of the first insertion layer 335. Finally, a third free layer 350 is disposed on the second insertion layer 345, and a capping layer 355 is formed on the third free layer 350. The capping layer 355 includes one or more of Ir, Os, Te, or Tl, and serves to reinforce in-plane anisotropy in the underlying free layer structure.

This free layer stack, composed of alternating ferromagnetic and IMA-insertion layers, provides enhanced magnetic tunability, allowing for precise control of switching thresholds, anisotropy orientation, and thermal stability. The IMA layers at the internal interfaces, in combination with the final IMA capping layer, increases the frequency of thermally-activated precession between states by amplifying the out-of-plane magnetic field that arises whenever the thermally-driven magnetization precession results in an out-of-plane magnetization component.

In another embodiment, the number of ferromagnetic sub-layers and insertion layers may be varied per device. For example, a free layer stack may include only two ferromagnetic sub-layers separated by a single IMA-inducing insertion layer, or may include four or more ferromagnetic sub-layers separated by multiple insertion layers. In still other embodiments, the insertion layers may be replaced or combined with ultrathin non-magnetic spacers, such as Ru or Rh or their alloys, to adjust interlayer coupling while maintaining in-plane anisotropy.

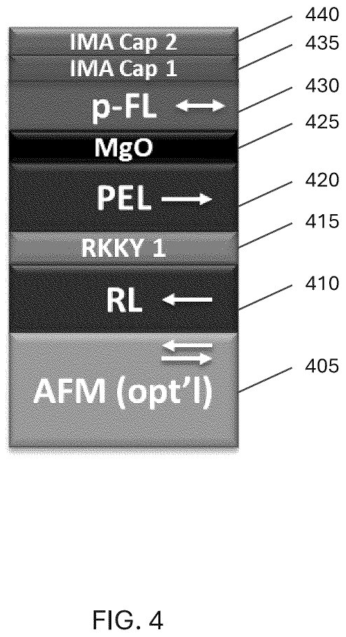

FIG. 4 is a cross-sectional diagram of an MTJ device including a dual capping structure over the free layer, according an embodiment.

In particular, FIG. 4 is a cross-sectional view of an MTJ device according to another embodiment. The structure of device shown in FIG. 4 is similar to that of device shown in FIG. 2, and includes an AFM layer 405, a RL 410, a first coupling layer (RKKY1) 415, a polarization enhancement layer (PEL) 420, a tunnel barrier layer 425, and a probabilistic free layer 430. As in the prior embodiments, the AFM layer 405 may include one or more AFM materials such as PtMn or IrMn to pin the magnetization of the RL 410, which may be formed of CoFe or CoFeB. The coupling layer 415 may include Ru, Ir, Rh, or Os to facilitate RKKY-type coupling with the intermediate magnetic layer 420, which may also include CoFeB and function as part of a SAF structure. The tunnel barrier layer 425, which may be formed of MgO, separates the fixed and free layers and effectuates spin-dependent tunneling. In alternative embodiments, the AFM layer 405 can be omitted.

In contrast to earlier embodiments, the MTJ device includes a dual-capping structure over the probabilistic free layer 430. The free layer 430 may be composed of a ferromagnetic material such as CoFeB, and is configured to operate in a stochastic regime suitable for use in probabilistic logic and random number generation. A first capping layer 435 is disposed directly on the free layer 430, and includes at least one of Ir, Os, Te, or Tl. This first capping layer 435 is configured to induce IMA in the free layer 430. To further enhance the performance and reliability of the device, a second capping layer 440 is disposed on the first capping layer 435. The second capping layer 440 includes one or more of scandium nitride (ScN), aluminum nitride (AlN), indium nitride (InN), yttrium nitride (YN), aluminum oxide (AlO), hafnium oxide (HfO), or titanium carbide (TiC). These materials are selected because they provide a stable and strong surface that protects the underlying IMA-inducing layer from oxidation, diffusion or degradation during subsequent processing. This is important because it reduces defect formation, preserves the integrity of the IMA interface and ensures consistent stochastic switching performance over time. In addition, the second capping layer 540 can impose a high strain in the free layer further enhancing IMA effect.

The dual-capping configuration provides independent tuning of IMA by interfacial effect and strain, allowing for higher degree of IMA to enhance the frequency of thermally-activated precession between states by amplifying the out-of-plane magnetic field that arises whenever the thermally-driven magnetization precession results in an out-of-plane magnetization component.

In another embodiment, the dual-capping structure may be extended to include additional protective or functional layers. For example, a third capping layer may be formed over the second capping layer to provide enhanced diffusion barriers, higher stress levels or compatibility with processing. In still other embodiments, the second capping layer may be selected from oxides or carbides (e.g., Al₂O₃, HfO₂, TiC) that further stabilize the underlying IMA-inducing layer and maintain interface quality during thermal cycling.

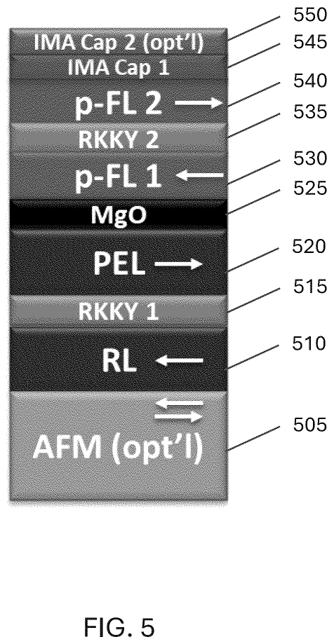

FIG. 5 is a cross-sectional diagram of a magnetic device including a SAF free layer structure coupled through an RKKY spacer, according to an embodiment.

In particular, FIG. 5 is a cross-sectional view of an MTJ device according to another embodiment of the present disclosure. The lower portion of the device in FIG. 5 is similar to that of FIGS. 2-4 and includes an AFM layer 505, a RL 510, a first coupling layer (RKKY1) 515, and an intermediate magnetic layer (PEL) 520, all of which may be constructed and function as previously described. A tunnel barrier layer 525, such as MgO, is disposed on the polarization enhancement layer 520, separating the fixed stack from a composite free layer structure. In alternative embodiments, the AFM layer 505 can be omitted.

In this embodiment, the free layer region comprises two ferromagnetic layers magnetically coupled via a non-magnetic spacer layer. A first free layer 530 is disposed on the tunnel barrier layer 525. A second coupling layer (RKKY2) 535 is formed on the first free layer 530, and may include one or more of Ru, Ir, Rh, or Os to facilitate RKKY coupling. A second free layer 540 is disposed on the second coupling layer 535. Each of the first and second free layers 530, 540 may include a ferromagnetic material such as CoFeB and be configured to operate in a stochastic regime, suitable for probabilistic or neuromorphic computing applications. The thickness of the second coupling layer 535 may be selected to induce either ferromagnetic or AFM coupling between the free layers 530 and 540. Together, the first and second free layers 530 and 540 and the second coupling layer 535 form a SAF structure within the free layer region.

Disposed on the second free layer 540 is a first IMA inducing capping layer 545, which includes at least one of Ir, Os, Te, or Tl. This layer enhances the in-plane anisotropy of the underlying magnetic structure via interfacial spin-orbit coupling. A second capping layer 550 is formed on the first IMA inducing capping layer 545 and may include one or more of ScN, AlN, InN, YN, AlO, HfO, or TiC. The second capping layer 550 may enhance the IMA level by strain engineering and chemically stabilize the IMA interface, or provide structural passivation, thereby improving thermal robustness and switching consistency.

The dual free-layer SAF design of FIG. 5 offers additional degrees of control over the composite magnetic state, including tunable effective anisotropy, reduced noise margin, and tailored energy barriers. This provides improved stochastic switching performance at high frequencies, supporting p-bit applications requiring low error rates and tunable stochasticity.

In another embodiment, the SAF structure may include more than two ferromagnetic layers coupled by multiple RKKY spacer layers. Alternatively, the spacer layer may be formed from alloys or multilayers (e.g., Ru/Ir, Ru/Rh).

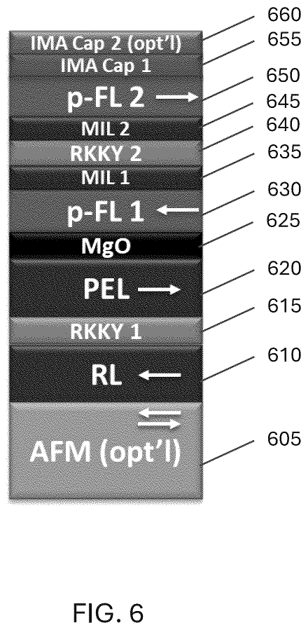

FIG. 6 is a cross-sectional diagram of a magnetic device including an SAF free layer structure with embedded magnetic insertion layers, according to an embodiment.

In particular, FIG. 6 is a cross-sectional view of an MTJ device in accordance with another embodiment of the present disclosure. The device of FIG. 6 includes structural elements similar to those shown in FIGS. 2-4, such as an AFM layer 605, a RL 610, a first coupling layer (RKKY1) 615, and an intermediate magnetic layer (PEL) 620. A tunnel barrier layer 625, such as MgO, is disposed on the intermediate magnetic layer 620 and separates the fixed stack from a composite free layer region. In alternative embodiments, the AFM layer 605 can be omitted.

The free layer structure in this embodiment is based on a SAF configuration and includes additional magnetic insertion layers. Disposed on the tunnel barrier layer 625 is a first probabilistic free layer (p-FL) 630. A first magnetic insertion layer (MIL1) 635 is disposed on the first p-FL 630, followed by a second coupling layer (RKKY2) 640, which may include Ru, Ir, Rh, or Os and is configured to provide RKKY-type magnetic coupling. A second magnetic insertion layer (MIL2) 645 is disposed on the second coupling layer 640. On MIL2 645 is a second probabilistic free layer (p-FL) 650. The two p-FLs 630 and 650 and the intervening layers form a synthetic free layer structure with tunable coupling characteristics.

Each magnetic insertion layer (MIL1, MIL2) may include a ferromagnetic material such as iron (Fe) or cobalt (Co), and may be included to enhance the degree of IMA at the interface, interfacial quality, and adjust the effective magnetic thickness. The thicknesses of the RKKY2 coupling layer 640 and the insertion layers 635 and 645 may be selected to establish ferromagnetic or antiferromagnetic coupling between the free layers 630 and 650, depending on the desired magnetic behavior of the composite structure. For example, RKKY layers can be about 0.2 nm-1.0 nm thick. In alternative embodiments, the thickness of the insertion layer can be different from the stated range.

A first IMA inducing capping layer 655 is disposed on the second p-FL 650 and may include one or more of Ir, Os, Te, or Tl. This layer induces IMA via interfacial spin-orbit coupling, which supports high-frequency stochastic switching by biasing the magnetization direction while allowing thermal fluctuation. A second capping layer 660 is disposed on the IMA cap and may include one or more of ScN, AlN, InN, YN, AlO, HfO, or TiC which can function as a passivation layer, or an additional interface tuner.

The SAF-based free layer configuration with embedded magnetic insertion layers allows for more precise tuning of the energy landscape of the device. This structure enhances the controllability of the p-bit flipping frequency and provides robustness against thermal noise and process variation, making it suitable for probabilistic logic, neuromorphic computing, and true random number generation applications.

In certain embodiments, the magnetic damping of the probabilistic free layer (p-FL) may be increased to further enhance the frequency of stochastic magnetization switching. Increased damping can support faster p-bit flipping by promoting quicker relaxation of magnetization after perturbation. This damping enhancement may be achieved by doping the p-FL or adjacent layers (e.g., the IMA cap) with elements such as gadolinium (Gd), terbium (Tb), platinum (Pt), or other similar materials. When combined with the IMA induced by the IMA capping layer, the increased damping effectuates finely tuned, high-speed operation of the magnetic device, and can be useful in probabilistic logic and random number generation applications.

In another embodiment, additional insertion layers may be incorporated at different positions within the free layer stack, such as between a probabilistic free layer and the tunnel barrier, or between a probabilistic free layer and the capping layer. These insertion layers may include IMA-inducing materials or alternative interface modifiers, such as oxides or nitrides, that further tune spin injection efficiency and anisotropy orientation. In still other embodiments, the SAF configuration may include more than two probabilistic free layers, with alternating insertion and coupling layers, to create a multi-p-FL structure offering additional control of stochastic switching frequency.

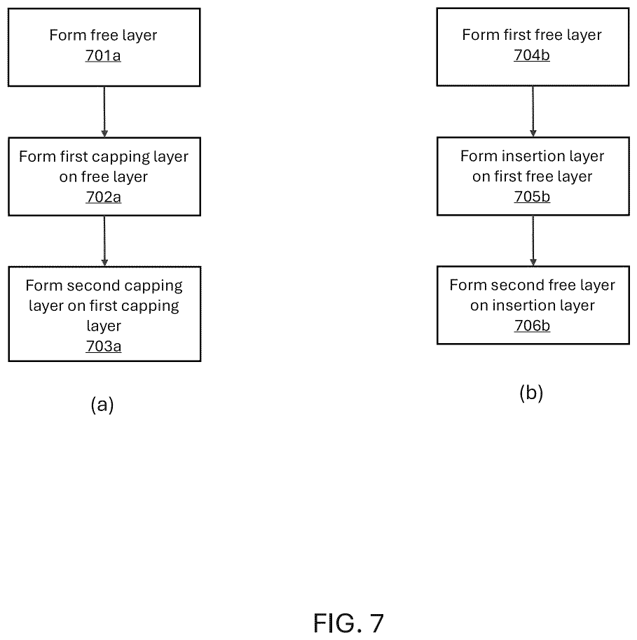

In FIG. 7, (a) is a flowchart of a method of forming a magnetic device operative for stochastic switching, according to an embodiment. In step 701a, a free layer is formed on a tunnel barrier that is disposed over a reference layer of an MTJ stack. The free layer comprises a ferromagnetic material, such as a transition-metal ferromagnet (e.g., Fe, Co, Ni) or an alloy thereof (e.g., CoFe, CoFeB, FeCo, or NiFe). The free layer is designed to operate in a stochastic switching regime, where thermally driven transitions between magnetic states implement probabilistic bit (p-bit) behavior. The free layer may be deposited using thin-film techniques, such as sputtering or evaporation, and may be annealed to promote crystallinity and interface quality with an underlying tunnel barrier.

In step 702a, a first capping layer can be deposited directly on the free layer. The first capping layer includes an IMA-inducing material. Examples include heavy elements such as Ir, Os, Te, or Tl, though other suitable materials may be used. The first capping layer can be deposited to a thickness of about 0.2 nm-1.0 nm to stabilize in-plane magnetization while reducing the energy barrier for switching, thereby enabling fast, thermally driven stochastic behavior.

In step 703a, a second capping layer is formed over the first capping layer. The second capping layer comprises a protective or passivation material, such as ScN, AlN, InN, YN, AlO, HfO, or TiC, and serves to enhance structural and chemical stability of the underlying first capping layer and free layer interface. In some embodiments, the second capping layer also relieves strain and improves device reliability without substantially altering the anisotropy set by the first capping layer. The second capping layer thus provides surface protection during subsequent device integration steps while maintaining the desired stochastic switching characteristics of the MTJ device.

Following step 703a, the MTJ stack may be patterned and integrated into circuits configured for probabilistic computing or random number generation.

In FIG. 7, (b) is another flowchart of a method of forming a magnetic device operative for stochastic switching, according to an embodiment. In step 704b, a first free layer comprising a ferromagnetic material (e.g., CoFe, CoFeB, FeCo, or NiFe) is formed on a tunnel barrier of a magnetic tunnel junction stack. In step 705b, an insertion layer is deposited on the first free layer. The insertion layer includes an IMA-inducing material, such as Ir, Os, Te, or Tl, and is configured to modify interfacial anisotropy and establish magnetic coupling between adjacent free layers. In step 706b, a second free layer comprising a ferromagnetic material is formed on the insertion layer, thereby completing a composite free layer stack. The combination of alternating free layers and insertion layer(s) allows tuning of anisotropy, switching frequency and thermal stability for stochastic operation.

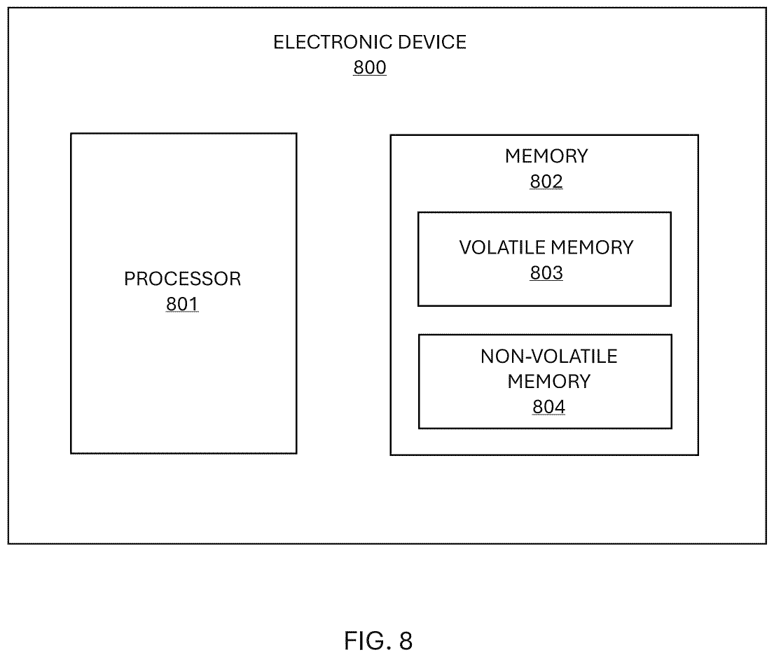

FIG. 8 is a block diagram of an electronic device having a memory that incorporates MTJ structures and methods described in FIGS. 1-7, according to an embodiment.

Referring to FIG. 8, an electronic device 800, e.g., a user equipment (UE) or a mobile terminal, includes a processor 801 and a memory 802. Although not illustrated in FIG. 8, dependent on the type of the electronic device 800, the electronic device 800 may include various additional components, such as an input device, a sound output device, a display device, an audio module, a sensor module, an interface, a haptic module, a camera module, a power management module, a battery, a communication module, a subscriber identification module (SIM), and/or an antenna module.

The processor 801 may execute, for example, software (e.g., a program) to control at least one other component (e.g., a hardware or a software component) of the electronic device 800, and may perform various data processing or computations. As at least part of the data processing or computations, the processor 801 may load a command or data received from another component in volatile memory 803, process the command or the data stored in the volatile memory 803, and store resulting data in non-volatile memory 804. The processor 801 may include a main processor (e.g., a central processing unit (CPU) or an application processor, and an auxiliary processor (e.g., a graphics processing unit (GPU), an image signal processor (ISP), a sensor hub processor, or a communication processor (CP)) that is operable independently from, or in conjunction with, the main processor.

The memory 802 may store various data used by at least one component (e.g., the processor 801) of the electronic device 800. The various data may include, for example, software (e.g., the program) and input data or output data for a command related thereto. The memory 802 may include the volatile memory 803 or the non-volatile memory 804. The non-volatile memory 804 includes a memory cell/unit of a magnetic device, e.g., as illustrated in FIGS. 2-7.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

While the present disclosure has been shown and described with reference to certain embodiments thereof, it will be understood by those skilled in the art that various changes in form and details may be made therein without departing from the spirit and scope of the disclosure as defined by the appended claims and their equivalents.

What is claimed is:

1. A magnetic device comprising:
a first free layer, wherein the first free layer includes a ferromagnetic material; and
a first capping layer disposed on the first free layer, wherein the first capping layer includes an in-plane anisotropy inducing material.

2. The magnetic device of claim 1, wherein the first capping layer includes at least one of Ir, Os, Te or Tl.

3. The magnetic device of claim 1, wherein the first free layer includes ferromagnetic alloys.

4. The magnetic device of claim 1, further comprising:
a reference layer;
a coupling layer disposed on the reference layer;
an intermediate magnetic layer disposed on the coupling layer; and
a tunneling barrier disposed on the intermediate magnetic layer.

5. The magnetic device of claim 1, further comprising a reference layer disposed on an antiferromagnetic material layer.

6. The magnetic device of claim 1, further comprising a second free layer, wherein an insertion layer is disposed between the first free layer and the second free layer.

7. The magnetic device of claim 1, further comprising a second capping layer disposed on the first capping layer.

8. The magnetic device of claim 1, further comprising:
a reference layer;
a first coupling layer disposed on the reference layer;
a tunneling barrier;
a second free layer disposed on the tunneling barrier; and
a second coupling layer disposed between the first free layer and the second free layer.

9. The magnetic device of claim 1, wherein the magnetic device forms part of a circuit operative to perform probabilistic computing or random number generation.

10. A system comprising:
a circuit; and
a magnetic tunnel junction (MTJ) device within the circuit, the MTJ device including:
a reference layer having a fixed magnetization direction;
a tunnel barrier disposed on the reference layer;
a free layer disposed on the tunnel barrier, the free layer including a ferromagnetic material; and
a capping layer disposed on the free layer, wherein the capping layer includes an in-plane anisotropy inducing material.

11. The system of claim 10, wherein the capping layer includes at least one of Ir, Os, Te or Tl.

12. The system of claim 10, wherein the capping layer is in direct contact with the free layer.

13. The system of claim 10, wherein the circuit is operative to perform probabilistic computing or random number generation.

14. The system of claim 10, wherein the MTJ device further comprises a second free layer, wherein an insertion layer is disposed between the first free layer and the second free layer.

15. The system of claim 10, wherein the MTJ device further comprises a second capping layer disposed on the first capping layer.

16. A method of forming a magnetic device comprising:
forming a first free layer including a ferromagnetic material;
forming a second free layer including a ferromagnetic material; and
disposing an insertion layer between the first free layer and the second free layer, wherein the insertion layer includes an in-plane anisotropy inducing material.

17. The method of claim 16, wherein the insertion layer comprises at least one of Ir, Os, Te or Tl.

18. The method of claim 16, further comprising disposing a capping layer on the first free layer.
